(19) United States
(12) Patent Application Publication
(10) Pub. No.: US 2026/0139154 A1
(43) Pub. Date: May 21, 2026

(54) CMP SLURRY COMPOSITION FOR POLISHING PATTERNED TUNGSTEN WAFER AND METHOD OF POLISHING PATTERNED TUNGSTEN WAFER USING THE SAME

(71) Applicant: SAMSUNG SDI CO., LTD., Yongin-si (KR)

(72) Inventors: Ji Ho LEE, Suwon-si (KR); Ji Hye KIM, Suwon-si (KR); Jin Gyo KIM, Suwon-si (KR); Eui Rang LEE, Suwon-si (KR); Ji Won BAEK, Suwon-si (KR); A Reum JUNG, Suwon-si (KR); Jun Ho YUN, Suwon-si (KR); Eun Bi PARK, Suwon-si (KR); Min A KWON, Suwon-si (KR); Kun Bae NOH, Suwon-si (KR)

(73) Assignee: SAMSUNG SDI CO., LTD., Yongin-si (KR)

(21) Appl. No.: 19/386,669

(22) Filed: Nov. 12, 2025

(30) Foreign Application Priority Data
Nov. 16, 2024 (KR) 10-2024-0163687

(51) Int. Cl. C09G 1/02; B24B 37/04; H01L 21/321

(52) U.S. Cl. CPC C09G 1/02; B24B 37/044; H10P 52/403

(57) ABSTRACT

Disclosed herein are a CMP slurry composition for polishing patterned tungsten wafers, and a method of polishing patterned tungsten wafers using the CMP slurry composition. The CMP slurry composition includes at least one of a polar solvent and a nonpolar solvent, an abrasive agent, and a catalyst. The catalyst includes a copper-containing catalyst, the copper-containing catalyst being a complex of a copper cation and a complexing agent having a charge of +1 or more at a pH in a range of 3 to 6.

### CROSS-REFERENCE TO RELATED APPLICATION

The present application claims priority to Korean Patent Application No. 10-2024-0163687, filed on Nov. 16, 2024 in the Korean Intellectual Property Office, the entire disclosure of which is incorporated herein by reference.

### FIELD OF THE DISCLOSURE

The present disclosure relates to a CMP slurry composition for polishing patterned tungsten wafers, and a method of polishing patterned tungsten wafers using the CMP slurry composition.

### DESCRIPTION OF THE RELATED ART

Chemical mechanical polishing (CMP) compositions and methods for polishing (or planarizing) a surface of a substrate are known in the art. Polishing compositions for polishing a metal layer (such as tungsten) on a semiconductor substrate may include abrasive particles suspended in an aqueous solution, and chemical accelerators such as oxidizing agents, catalysts, and the like.

A process of polishing a metal layer using a CMP composition includes the steps of polishing an initial metal layer, polishing the metal layer and a barrier layer, and polishing the metal layer, the barrier layer, and an oxide film. A CMP slurry composition for polishing patterned tungsten wafers may be used in the step of polishing the metal layer, the barrier layer, and the oxide film. To achieve desired planarization, the metal layer and the oxide film may be polished at appropriate polishing rates.

### SUMMARY

An aspect of the present disclosure includes a CMP slurry composition for polishing patterned tungsten wafers, and an enhanced polishing rate and an improved flatness of a polished surface upon polishing a patterned tungsten wafer.

Another aspect of the present disclosure includes a method of polishing patterned tungsten wafers using the CMP slurry composition.

An aspect of the present disclosure includes a CMP slurry composition for polishing patterned tungsten wafers.

The CMP slurry composition for polishing patterned tungsten wafers includes at least one of a polar solvent and a nonpolar solvent, an abrasive agent, and a catalyst. The catalyst includes a copper-containing catalyst, and the copper-containing catalyst is or includes a complex of a copper cation and a complexing agent having a charge of +1 or more at a pH in a range of about 3 to about 6.

An aspect of the present disclosure includes a method of polishing patterned tungsten wafers.

The method of polishing patterned tungsten wafers includes polishing a patterned tungsten wafer using the CMP slurry composition for polishing patterned tungsten wafers according to the present disclosure.

Example embodiments of the present disclosure include a CMP slurry composition for polishing patterned tungsten wafers, which provides an enhanced polishing rate and improved flatness of a polished surface during polishing of patterned tungsten wafers.

### DETAILED DESCRIPTION

The terminology used herein is for the purpose of describing example embodiments, and is not intended to limit the present disclosure. As used herein, the singular forms “a”, “an”, and “the” are intended to include the plural forms as well, unless the context clearly indicates otherwise.

As used herein, “substituted” in “substituted or unsubstituted” means that at least one hydrogen atom in a corresponding functional group is substituted with —NRₐR_{b}, a hydroxyl group, a C₁ to C₂₀ alkyl or haloalkyl group, a C₂ to C₂₀ alkenyl or haloalkenyl group, a C₂ to C₂₀ alkynyl or haloalkynyl group, a C₃ to C₂₀ cycloalkyl group, a C₃ to C₂₀ cycloalkenyl group, a C₆ to C₂₀ aryl group, a C₇ to C₂₀ arylalkyl group, a C₁ to C₂₀ alkoxy group, a C₆ to C₂₀ aryloxy group, a halogen group, a cyano group, or a thiol group. Rₐ and R_{b} are each independently hydrogen or a C₁ to C₅ alkyl group.

As used herein to represent a specific numerical range, the expression “X to Y” means “greater than or equal to X and less than or equal to Y”.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

In accordance with one example embodiment of the present disclosure, a CMP slurry composition for polishing patterned tungsten wafers has a pH in a range of 3 about to about 6 and provides both enhanced tungsten removal rate and improved flatness of a polished surface during polishing of patterned tungsten wafers. Improvement in flatness of a polished surface is confirmed by reduction in erosion, protrusion, or scratch defects on polished wafer surfaces.

In one example embodiment, the pH range of about 3 to about 6 is set in consideration of use of an abrasive agent described below. Within the above range of pH, the abrasive agent described below can achieve a high tungsten removal rate.

The CMP slurry composition for polishing patterned tungsten wafers according to the present disclosure includes at least one of polar solvent or a nonpolar solvent, an abrasive agent, and a catalyst, wherein the catalyst includes a copper-containing catalyst, and the copper-containing catalyst is a complex of a copper cation and a complexing agent having a charge of +1 or more at a pH in a range of about 3 to about 6.

The CMP slurry composition is configured to improve a tungsten removal rate and flatness of a polished surface upon polishing a patterned tungsten wafer at a pH in a range of about 3 to about 6.

A composition including only an iron-containing catalyst described below at a pH in a range of about 3 to about 6 can cause increased erosion and reduced flatness of a patterned tungsten wafer, despite having the ability to improve a tungsten removal rate. In this regard, the CMP slurry composition according to one example embodiment can provide an enhanced tungsten removal rate and improved flatness of a polished surface at a pH in a range of about 3 to about 6 due to the presence of the copper-containing catalyst.

A composition including a copper-containing catalyst free from a complexing agent having a charge of +1 or more at a pH in a range of about 3 to about 6 can cause increased tungsten elution and reduced flatness of a polished surface, despite having the ability to improve a tungsten removal rate.

A composition including an iron-containing catalyst and a complexing agent having a charge of +1 or more at a pH in a range of about 3 to about 6 can cause a reduced tungsten removal rate and poor flatness of a polished surface at the same removal amount, despite having the ability to reduce or suppress increase in tungsten elution.

A composition including a copper-containing catalyst containing a complexing agent having a charge of less than +1 at a pH in a range of about 3 to about 6 can cause increased tungsten elution and poor flatness of a polished surface.

The copper-containing catalyst is a complex of a copper cation and a complexing agent having a charge of +1 or more at a pH in a range of about 3 to about 6. In the CMP slurry composition according to the present disclosure, the copper cation forms a complex with the complexing agent having a charge of +1 or more at a pH in a range of about 3 to about 6, rather than being present in a free state. The CMP slurry composition includes the complex.

In one example embodiment, the copper cation may include a copper (II) cation. The copper (II) cation may be derived from copper acetate and the like.

In one example embodiment, the complexing agent may have a charge of +1 to +10 at a pH in a range of about 3 to about 6. Within this range, the complexing agent can reduce or suppress elution of tungsten and improve flatness of a polished surface.

The complexing agent may include at least one of arginine, lysine, histidine, polyarginine, polylysine, and polyamidoamine.

The polyarginine may be prepared by condensation of arginine, and the polylysine may be prepared by condensation of lysine. Herein, condensation may include formation of a peptide bond between an amine group and a carboxylic acid group of arginine or lysine.

The polyamidoamine may be or include a non-dendrimeric polyamidoamine.

The non-dendrimeric polyamidoamine may refer to a random hyperbranched copolymer having a plurality of amidoamine units while not having a dendrimeric structure.

Herein, the “dendrimeric structure” refers to a macromolecule with a highly ordered, branched structure from a core thereof to a surface thereof.

A random hyperbranched structure can be effectively adsorbed onto tungsten in an acidic pH range, thereby reducing corrosion of a patterned tungsten wafer while improving flatness of a polished surface.

The non-dendrimeric polyamidoamine may have at least one of a primary amine group (NH₂), a secondary amine group (NH), a carboxyl group (COOH), and COOZ (where Z is a C₁ to C₄ alkyl group) at a terminal thereof or in a molecular structure thereof. Each of the primary amine group (NH₂) and the secondary amine group (NH) allows the non-dendrimeric polyamidoamine to be effectively bonded to a tungsten surface, thereby reducing corrosion of a patterned tungsten wafer. Each of the carboxyl group (COOH) and COOZ facilitates access of the abrasive agent upon adsorption of the non-dendrimeric polyamidoamine onto a tungsten surface in an acidic pH range, thereby reducing or minimizing reduction in polishing rate with respect to a patterned tungsten wafer.

For example, the non-dendrimeric polyamidoamine has at least one of a primary amine group (NH₂) and a secondary amine group (NH); and at least one of a carboxyl group (COOH) and COOZ (where Z is a C₁ to C₄ alkyl group) at a terminal thereof or in a molecular structure thereof.

In one example embodiment, the non-dendrimeric polyamidoamine has a main chain composed of or including an amide group (—CONH—) and a secondary amine group (—NH); and a terminal functional group composed of or including an amine group including a primary amine group (—NH₂) and a secondary amine group (NH), a carboxyl group (COOH), and COOZ (where Z is a C₁ to C₄ alkyl group). A proportion of the carboxyl group (COOH) and COOZ in the terminal functional group may range from about 10% to about 60%, for example 20% to 40%. Within this range, the non-dendrimeric polyamidoamine can reduce or minimize reduction in polishing rate with respect to a patterned tungsten wafer. Herein, the “proportion of COOH and COOZ in the terminal functional group” may refer to an area ratio of COOH and COOZ to the amine group, as measured by, e.g., a nuclear magnetic resonance (NMR) assay.

Each of, or at least one of, the primary amine group and the secondary amine group may be modified by a predetermined method. For example, each of, or at least one of, the primary amine group and the secondary amine group may be modified through reaction with a compound having at least one of a cyclic carbonate group, an isocyanate group, an anhydride group, an acrylate group, or an epoxy group.

In one example embodiment, in the non-dendrimeric polyamidoamine, at least one of the primary amine group (NH₂), the secondary amine group (NH), the carboxyl group (COOH), COOZ, and —C(═O)—NH— may be linked by a linear or branched aliphatic hydrocarbon group (for example, a polyvalent C₁ to C₁₀ aliphatic hydrocarbon group).

The non-dendrimeric polyamidoamine may be prepared by reacting an ester having at least one ester group and at least one C═C bond with an amine having at least one primary amine group. In one example embodiment, the non-dendrimeric polyamidoamine may be prepared by reacting an ester having at least one ester group and at least one C═C bond with a diamine having two primary amine groups.

In one example embodiment, the non-dendrimeric polyamidoamine may include a commercially available product (for example, Helux 3316 (having a chemical structure as shown below)).

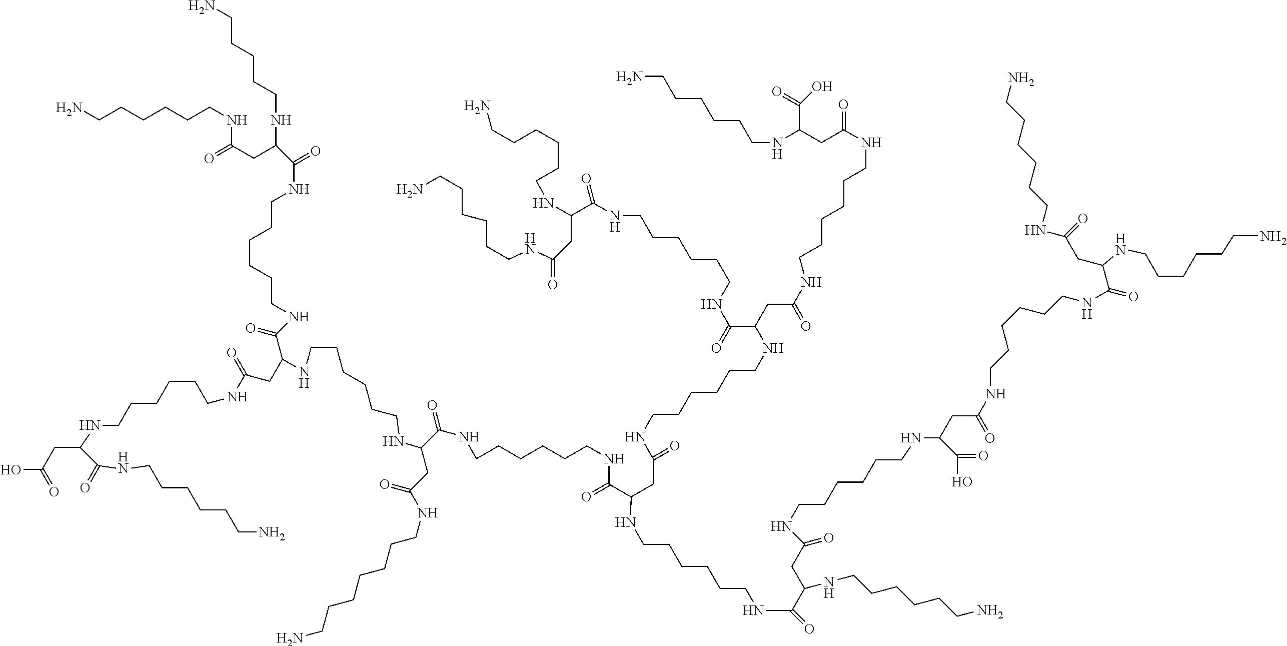 [SMILES: NCCCCCCCNC(=O)CC(NCCCCCCNC(CC(=O)NCCCCCCNC(CC(=O)O)C(=O)NCCCCCCN)C(=O)NCCCCCCNC(=O)C(CC(=O)NCCCCCCN)NCCCCCN)C(=O)NCCCCCCNC(=O)C(CC(=O)NCCCCCCNC(CC(=O)NCCCCCCNC(=O)CC(NCCCCCCN)C(=O)O)C(=O)NCCCCCCNC(=O)C(CC(=O)NCCCCCCN)NCCCCCCN)NCCCCCCNC(=O)C(CC(=O)NCCCCCCNC(CC(=O)NCCCCCCNC(=O)C(CC(=O)NCCCCCCN)NCCCCCCN)C(=O)O)NCCCCCCN]

In one example embodiment, the complexing agent having a charge of +1 or more at a pH in a range of about 3 to about 6 may be arginine. The arginine can significantly improve flatness of a polished surface.

The copper cation may be present in an amount in a range of about 1 ppm to about 1,000 ppm, for example, 1 ppm to 500 ppm, for example 1 ppm to 200 ppm, or for example about 5 ppm to about 100 ppm, 1, 5, 10, 15, 20, 25, 30, 35, 40, 45, 50, 55, 60, 65, 70, 75, 80, 85, 90, 100, 105, 110, 115, 120, 125, 130, 135, 140, 145, 150, 155, 160, 165, 170, 175, 180, 185, 190, 195, 200 ppm, in the CMP slurry composition. Within this range, the copper cation can enhance a polishing rate with respect to patterned tungsten wafers.

Herein, the content of each of the copper cation and an iron cation described below may be determined by elemental analysis. For example, the content of each of the copper cation and the iron cation may be determined by sequentially performing sampling and pretreatment, followed by measurement using an inductively coupled plasma optical emission spectrometer (ICP-OES).

The complexing agent having a charge of +1 or more at a pH in a range of about 3 to about 6 may be present in an amount in a range of about 0.001 wt % to about 3 wt %, for example, about 0.01 wt % to about 1 wt %, in the CMP slurry composition. Within this range, the complexing agent can improve flatness of polished wafer surfaces.

The catalyst may further include an iron-containing catalyst.

The iron-containing catalyst may further enhance a tungsten removal rate.

In one example embodiment, the iron-containing catalyst may include at least one of an iron ion complex and a hydrate thereof. The at least one of an iron ion complex and a hydrate thereof can enhance a polishing rate with respect to patterned tungsten wafers.

The iron ion complex may include a ferric cation-containing complex. The ferric cation-containing complex may include a compound formed by reaction of a ferric cation in an aqueous solution state with an organic or inorganic compound having at least one functional group such as or including at least one of among carboxylic acids, phosphoric acids, sulfuric acids, amino acids, and amines, or a salt thereof. The organic or inorganic compound may include at least one of citrate, ammonium citrate, p-toluenesulfonic acid (pTSA), 1,3-propylenediaminetetraacetic acid (PDTA), ethylenediaminetetraacetic acid (EDTA), diethylenetriaminepentaacetic acid (DTPA), nitrilotriacetic acid (NTA), and ethylenediamine-N,N′-disuccinic acid (EDDS), without being limited thereto. Examples of the ferric cation-containing complex may include at least one of ferric citrate, ammonium ferric citrate, Fe(III)-pTSA, Fe(III)-PDTA, Fe(III)-EDTA, and Fe(III)-DTPA, without being limited thereto.

In one example embodiment, the ferric cation may be derived from a ferric cation-containing compound. For example, the ferric cation-containing compound may include at least one of ferric chloride (FeCl₃), ferric nitrate (Fe(NO₃)₃), and ferric sulfate (Fe₂(SO₄)₃), without being limited thereto.

An iron cation of the iron-containing catalyst may be present in an amount in a range of about 1 ppm to about 1,000 ppm, for example, 1 ppm to 500 ppm, for example 1 ppm to 200 ppm, or for example 1 ppm to 50 ppm, 1, 5, 10, 15, 20, 25, 30, 35, 40, 45, 50, 55, 60, 65, 70, 75, 80, 85, 90, 100, 105, 110, 115, 120, 125, 130, 135, 140, 145, 150, 155, 160, 165, 170, 175, 180, 185, 190, 195, 200 ppm, in the CMP slurry composition. Within this range, the iron cation can enhance a polishing rate with respect to patterned tungsten wafers.

In one example embodiment, when the CMP slurry composition includes a mixture of the copper-containing catalyst and the iron-containing catalyst, the iron cation and the copper cation may be present in a weight ratio in a range of about 1:0.5 to about 1:10, for example, 1:0.5, 1:1, 1:1.5, 1:2, 1:2.5, 1:3, 1:3.5, 1:4, 1:4.5, 1:5, 1:5.5, 1:6, 1:6.5, 1:7, 1:7.5, 1:8, 1:8.5, 1:9, 1:9.5, 1:10, 1:1 to 1:5. Within this range, the CMP slurry composition can achieve an enhanced polishing rate and improved flatness of a polished surface.

The abrasive agent may polish an insulating layer (for example, a silicon oxide film) and a patterned tungsten wafer at a high polishing rate.

The abrasive agent may include an abrasive agent commonly used for polishing. For example, the abrasive agent may include metal or non-metal oxide abrasive particles. The abrasive agent may include, for example, at least one of among silica, such as colloidal silica and fumed silica, alumina, ceria, titania, and zirconia. In one example embodiment, the abrasive agent may include silica (for example, colloidal silica), without being limited thereto.

The abrasive agent includes spherical or non-spherical particles, and may have an average primary particle diameter (D50) in a range of about 10 nm to about 200 nm, for example 20 nm to 180 nm, or for example 30 nm to 150 nm. Within this range, the abrasive agent can achieve a high polishing rate with respect to patterned tungsten wafers, reduce or prevent scratches, and improve flatness of a polished surface.

Herein, “average particle diameter (D₅₀)” is a typical particle diameter measure known in the art and refers to a particle diameter of the abrasive particles corresponding to 50 vol % when the abrasive particles are distributed in order from smallest to largest in terms of volume.

In one example embodiment, the abrasive agent has a positive charge on a surface thereof and may have a surface potential of about +10 mV or more, for example, a range of about +10 mV to about +60 mV. Within this range, the abrasive agent can improve flatness of a polished surface while reducing post-polishing defects.

Herein, the surface potential of the abrasive agent may be determined by a zeta potential measurement method.

In one example embodiment, the abrasive agent may include non-modified abrasive particles, which are not subjected to surface modification.

In another example embodiment, the abrasive agent may include abrasive particles subjected to surface modification with a nitrogen-containing silane. The surface-modified abrasive particles may be more effective at achieving the desired effects of the present disclosure than the non-modified abrasive particles.

In one example embodiment, the abrasive agent may include silica subjected to surface modification with at least one of a silane having two nitrogen atoms and a silane having three nitrogen atoms. The modified silica can significantly improve a polishing rate and flatness of a polished surface and can significantly reduce scratches, compared to non-modified silica or silica modified with an aminosilane having one nitrogen atom. In addition, the modified silica can achieve a high polishing rate with respect to patterned tungsten wafers even at a weakly acidic pH, which is higher than the pH of typical strongly acidic CMP slurry compositions.

The modified silica has a positive charge on a surface thereof and may have a surface potential of about +10 mV or more, for example, about +10 m V to about +60 m V. Within this range, the modified silica can improve flatness of a polished surface while reducing post-polishing defects.

In one example embodiment, the abrasive agent may include silica modified with at least one of an aminosilane having two nitrogen atoms and an aminosilane having three nitrogen atoms described below.

Herein, the silica modified with at least one of an aminosilane having two nitrogen atoms and an aminosilane having three nitrogen atoms may be obtained by adding a modifying compound, a cation thereof, or a salt thereof to non-modified silica, followed by reaction for a predetermined period of time. Herein, the non-modified silica may include at least one of colloidal silica and fumed silica, for example colloidal silica.

### Silane Having Two Nitrogen Atoms

The silane having two nitrogen atoms includes a compound represented by Formula 1, a cation derived from the compound represented by Formula 1, or a salt of the compound represented by Formula 1:

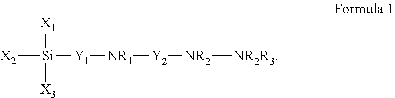

In Formula 1, X₁, X₂, and X₃ each independently is or includes hydrogen, halogen, a hydroxyl group, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group;
at least one of X₁, X₂, and X₃ is or includes a hydroxyl group, halogen, a substituted or unsubstituted C₁ to C₂₀ alkoxy group, or a substituted or unsubstituted C₆ to C₂₀ aryloxy group;
Y₁ and Y₂ each independently is or includes a divalent aliphatic hydrocarbon group, a divalent cycloaliphatic hydrocarbon group, or a divalent aromatic hydrocarbon group; and
R₁, R₂, and R₃ each independently is or includes hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

In one example embodiment, the abrasive agent includes silica modified with the compound represented by Formula 1.

For example, in Formula 1, X₁, X₂, and X₃ each independently is or includes a hydroxyl group, a substituted or unsubstituted C₁ to C₂₀ alkyl group, or a substituted or unsubstituted C₁ to C₂₀ alkoxy group, wherein at least one of X₁, X₂, and X₃ is or includes a hydroxyl group or a substituted or unsubstituted C₁ to C₂₀ alkoxy group. As another example, in Formula 1, X₁, X₂, and X₃ are or include a hydroxyl group or a substituted or unsubstituted C₁ to C₂₀ alkoxy group. This feature allows the compound represented by Formula 1 to be more stably bonded to the silica, thereby increasing lifespan of the abrasive agent.

For example, Y₁ and Y₂ each independently is or includes a divalent aliphatic hydrocarbon group, for example a C₁ to C₈ alkylene group.

For example, in Formula 1, R₁, R₂, and R₃ each independently is or includes hydrogen, such that the compound represented by Formula 1 may be or include a silane containing an amino group (—NH₂).

For example, the compound represented by Formula 1 may include at least one of aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysillane, and aminoethylaminomethylmethyldiethoxysilane.

In another example embodiment, the abrasive agent includes silica modified with a cation derived from the compound represented by Formula 1 above.

The cation derived from the compound represented by Formula 1 above refers to a cation formed by further bonding hydrogen or a substituent to at least one of the two nitrogen atoms in Formula 1. The cation may be or include a monovalent or divalent cation. For example, the cation may be represented by one of Formulas 1-1 to 1-3.

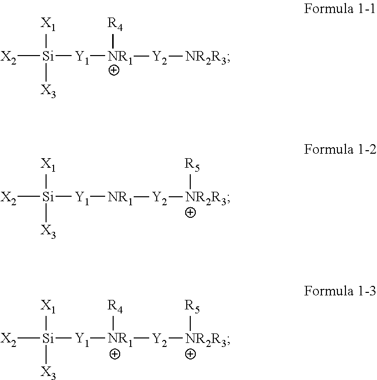

where each of X₁, X₂, X₃, Y₁, Y₂, R₁, R₂, and R³ is the same as defined above in Formula 1, and

R₄ and R₅ each independently is or includes hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

In a further example embodiment, the abrasive agent includes silica modified with a salt of the compound represented by Formula 1. The salt of the compound represented by Formula 1 refers to a neutral salt composed of or including an anion and a cation derived from the compound represented by Formula 1.

The cation may be represented by one of Formulas 1-1 to 1-3. The anion may include a halogen anion (for example, F⁻, Cl⁻, Br⁻, I⁻), a carbonate anion (for example, CO₃²⁻, HCO₃⁻), an organic acid anion such as an acetic acid anion (CH₃COO⁻) or a citric acid anion (HOC(COO⁻)(CH₂COO⁻)₂), a nitrogen-containing anion (for example, NO₃⁻, NO₂⁻), a phosphorus-containing anion (for example, PO₄³⁻, HPO₄²⁻, H₂PO₄⁻), a sulfur-containing anion (for example, SO₄²⁻, HSO₄⁻), a cyanide anion (CN⁻), and the like.

### Silane Having Three Nitrogen Atoms

The silane having three nitrogen atoms includes a compound represented by Formula 2 below, a cation derived from the compound represented by Formula 2, or a salt of the compound represented by Formula 2:

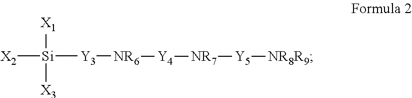

where X₁, X₂, and X₃ are the same as defined above in Formula 1;
Y₃, Y₄, and Y₅ each independently is or includes a single bond, a divalent aliphatic hydrocarbon group, a divalent cycloaliphatic hydrocarbon group, or a divalent aromatic hydrocarbon group; and
R₆, R₇, R₈, and R⁹ each independently is or includes hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

In one example embodiment, the abrasive agent includes silica modified with the compound represented by Formula 2.

For example, in Formula 2, X₁, X₂, and X₃ each independently is or includes a hydroxyl group, a substituted or unsubstituted C₁ to C₂₀ alkyl group, a substituted or unsubstituted C₁ to C₂₀ alkoxy group, wherein at least one of X₁, X₂, and X₃ is or includes a hydroxyl group or a substituted or unsubstituted C₁ to C₂₀ alkoxy group. As another example, in Formula 2, X₁, X₂, and X₃ are or include a hydroxyl group or a substituted or unsubstituted C₁ to C₂₀ alkoxy group. This feature allows the compound represented by Formula 2 to be more stably bonded to the silica, thereby increasing lifespan of the abrasive agent.

For example, in Formula 2, Y₃, Y₄, and Y₅ each independently is or includes a divalent aliphatic hydrocarbon group, for example a C₁ to C₅ alkylene group.

For example, in Formula 2, R₆, R₇, R₈, and R₉ each independently is or includes hydrogen, such that the compound represented by Formula 2 may be or include a silane containing an amino group (—NH₂).

For example, the compound represented by Formula 2 may include at least one of diethylenetriaminopropyltrimethoxysilane, diethylenetriaminopropyltriethoxysilane, diethylenetriaminopropylmethyldimethoxysilane, diethylenetriaminopropylmethyldiethoxysilane, and diethylenetriaminomethylmethyldiethoxysilane.

In another example embodiment, the abrasive agent includes silica modified with a cation derived from the compound represented by Formula 2. Thus, the modified silica has a positive charge on a surface thereof, thereby enhancing a polishing rate with respect to patterned tungsten wafers while improving flatness of a polished surface and reducing scratches.

The cation derived from the compound represented by Formula 2 refers to a cation formed by bonding hydrogen or a substituent to at least one of the three nitrogen atoms in Formula 2. The cation may be or include a monovalent, divalent, or trivalent cation. For example, the cation may be represented by one of Formulas 2-1 to 2-7.

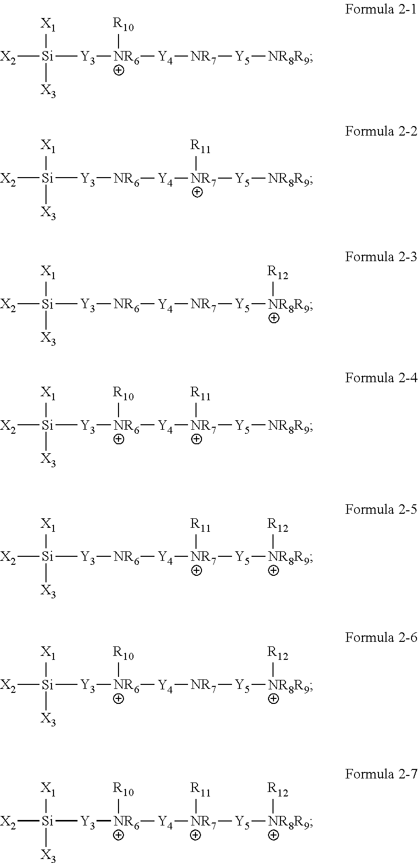

where each of X₁, X₂, X₃, Y₃, Y₄, Y₅, R₆, R₇, R₈, and R₉ is the same as defined above in Formula 2, and
R₁₀, R₁₁, and R₁₂ each independently is or includes hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

In a further example embodiment, the abrasive agent includes silica modified with a salt of the compound represented by Formula 2. The salt of the compound represented by Formula 2 refers to a neutral salt composed of or including an anion and a cation derived from the compound represented by Formula 2.

The cation may be represented by one of Formulas 2-1 to 2-7. The anion may be the same as or different from the anion described above related to the salt of the compound represented by Formula 1.

The abrasive agent, for example, the modified silica, may be present in an amount in a range of about 0.001 wt % to about 20 wt %, for example 0.01 wt % to 15 wt %, for example 0.05 wt % to 10 wt %, or for example 0.1 wt % to 10 wt % or 0.1 wt % to 5 wt %, in the CMP slurry composition. Within this range, the abrasive agent can polish an insulating layer film and a patterned tungsten wafer at a high polishing rate.

### Solvent

The at least one of a polar solvent and a nonpolar solvent reduces friction of the abrasive agent against a surface of a patterned tungsten wafer upon polishing the patterned tungsten wafer with the abrasive agent. The at least one of a polar solvent and a nonpolar solvent may include water (for example, ultrapure water or deionized water), organic amines, organic alcohols, organic alcohol amines, organic ethers, organic ketones, and the like. For example, the solvent includes ultrapure water or deionized water. The solvent may be present in the balance amount, for example, in an amount in a range of about 30 wt % to about 99 wt %, in the CMP slurry composition.

The CMP slurry composition may further include at least one of an oxidizing agent and an amino acid.

The oxidizing agent facilitates polishing of a patterned tungsten wafer by oxidizing the patterned tungsten wafer.

The oxidizing agent may include at least one of an inorganic per-compound, an organic per-compound, bromic acid or a salt thereof, nitric acid or a salt thereof, chloric acid or a salt thereof, chromic acid or a salt thereof, iodic acid or a salt thereof, iron or a salt thereof, copper or a salt thereof, a rare-earth metal oxide, a transition metal oxide, and potassium dichromate. Herein, “per-compound” refers to a compound containing at least one peroxide group (—O—O—), or containing an element in the highest oxidation state. For example, the oxidizing agent includes a per-compound. For example, the per-compound may include at least one of hydrogen peroxide, potassium periodate, calcium persulfate, and potassium ferricyanide, or for example, hydrogen peroxide.

The oxidizing agent may be present in an amount in a range of about 0.01 wt % to about 20 wt %, for example 0.05 wt % to 10 wt %, or for example 0.1 wt % to 5 wt %, in the CMP slurry composition. Within this range, the oxidizing agent can improve a polishing rate with respect to patterned tungsten wafers.

The amino acid reduces elution of tungsten.

The amino acid may include at least one of glycine, lysine, alanine, histidine, serine, glutamine, valine, leucine, phenylalanine, arginine, aspartic acid, glutamic acid, threonine, asparagine, cysteine, proline, and the like. For example, the amino acid includes at least one of glycine, lysine, alanine, and histidine, or for example glycine.

The amino acid may be present in an amount in a range of about 0.001 wt % to about 10 wt %, for example 0.005 wt % to 5 wt %, for example 0.01 wt % to 1 wt %, or for example 0.02 wt % to 0.5 wt %, in the CMP slurry composition. Within this range, the amino acid can reduce elution of a tungsten film.

The CMP slurry composition may have a pH in a range of about 3 to about 6, for example 3.5 to 6, for example 4 to 6, or for example 3.5 to 5. With the use of silica including the aforementioned compound or modified with the aforementioned compound as the abrasive agent, the present disclosure can achieve a high polishing rate with respect to patterned tungsten wafers even at a weakly acidic pH, which is higher than the pH of typical strongly acidic CMP slurry compositions.

The CMP slurry composition may further include a pH adjuster to adjust the pH of the composition to the above range.

In one example embodiment, the pH adjuster may include an inorganic acid, for example, at least one of nitric acid, phosphoric acid, hydrochloric acid, and sulfuric acid or an organic acid, for example, at least one of formic acid, acetic acid, and propionic acid. In another example embodiment, the pH adjuster may include a base, for example, at least one of aqueous ammonia, sodium hydroxide, potassium hydroxide, ammonium hydroxide, sodium carbonate, and potassium carbonate.

The pH adjuster may be present in an amount in a range of about 0.001 wt % to about 5 wt %, for example 0.002 wt % to 1 wt %, or for example 0.005 wt % to 0.5 wt %, in the CMP slurry composition.

The CMP slurry composition may further include additives such as biocides, surfactants, dispersants, modifiers, and surface active agents. The additives may be present in an amount in a range of about 0.001 wt % to about 5 wt %, for example 0.002 wt % to 1 wt %, or for example 0.005 wt % to 0.5 wt %, in the CMP slurry composition. Within this range, the additives can provide intended effects thereof without affecting a polishing rate with respect to patterned tungsten wafers.

In accordance with another aspect of the present disclosure, a method of polishing patterned tungsten includes polishing a patterned tungsten wafer using the CMP slurry composition for polishing patterned tungsten wafers according to the present disclosure.

The present disclosure is described in more detail below with reference to some examples. It should be understood that these examples are provided for illustration only and are not to be construed in any way as limiting the present disclosure.

Details of components used in Examples and Comparative Examples were as follows:
(1) Abrasive agent: Colloidal silica (PL-7, Fuso Chemical) having an average particle diameter (D50) of 120 nm was modified and used. For example, the unmodified abrasive agent was mixed with a compound represented by Formula 3, followed by reaction at a pH of 2.5 and a temperature of 25° C. for 72 hours, thereby preparing silica modified with the compound represented by Formula 3. The charge of the modified abrasive particles was changed by adjusting the content of the compound represented by Formula 3.

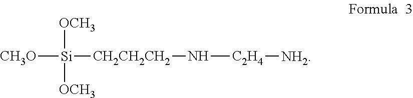

(2) pH adjuster: Acetic acid, nitric acid, or aqueous ammonia

### Example 1

Based on a total weight of a final CMP slurry composition, 2 wt % of the modified silica particles (average particle diameter (D50): about 120 nm, surface potential: about 15 mV) was mixed with 0.05 wt % of acetic acid, 0.005 wt % of copper acetate, 0.05 wt % of arginine, and the balance of deionized water, thereby preparing a CMP slurry composition containing a copper cation as shown in Table 1. The pH of the CMP slurry composition was adjusted to 4.5 using the pH adjuster. Immediately prior to polishing, hydrogen peroxide was mixed with the CMP slurry composition in an amount corresponding to 0.3 wt % of the total weight of the CMP slurry composition.

### Example 2

A CMP slurry composition containing a copper cation as shown in Table 1 was prepared in the same manner as in Example 1 except that, instead of the silica particles having a surface potential of about 15 mV, 2 wt % of silica particles having a surface potential of about 30 mV, prepared by adjusting the content of the compound represented by Formula 3, were used.

### Example 3

A CMP slurry composition containing a copper cation and an iron cation as shown in Table 1 was prepared in the same manner as in Example 2 except that 0.005 wt % of iron diethylenetriamine pentaacetate was further used.

### Example 4

A CMP slurry composition containing a copper cation and an iron cation as shown in Table 1 was prepared in the same manner as in Example 3 except that 0.05 wt % of lysine was used instead of arginine. Lysine had a charge of +1 at a pH of 4.5.

### Example 5

A CMP slurry composition containing a copper cation and an iron cation as shown in Table 1 was prepared in the same manner as in Example 3 except that 0.05 wt % of histidine was used instead of arginine. Histidine had a charge of +1 at a pH of 4.5.

### Example 6

A CMP slurry composition containing a copper cation and an iron cation as shown in Table 1 was prepared in the same manner as in Example 3 except that 0.01 wt % of polyamidoamine (Helux 3316, Polymer Factory) was used instead of arginine. Polyamidoamine (Helux 3316, Polymer Factory) had a charge of +5 to +10 at a pH of 4.5.

### Comparative Example 1

A CMP slurry composition containing an iron cation as shown in Table 2 was prepared in the same manner as in Example 1 except that 0.005 wt % of iron diethylenetriamine pentaacetate was used instead of copper acetate.

### Comparative Example 2

A CMP slurry composition containing an iron cation as shown in Table 2 was prepared in the same manner as in Example 2 except that 0.005 wt % of iron diethylenetriamine pentaacetate was used instead of copper acetate.

### Comparative Example 3

A CMP slurry composition containing a copper cation and an iron cation as shown in Table 2 was prepared in the same manner as in Example 3 except that 0.05 wt % of glycine was used instead of arginine. Glycine had a charge of zero at a pH of 4.5.

### Comparative Example 4

A CMP slurry composition containing a copper cation and an iron cation as shown in Table 2 was prepared in the same manner as in Example 3 except that 0.05 wt % of gamma-aminobutyric acid was used instead of arginine. Gamma-aminobutyric acid had a charge of zero at a pH of 4.5.

### Comparative Example 5

A CMP slurry composition containing a copper cation and an iron cation as shown in Table 2 was prepared in the same manner as in Example 3 except that 0.05 wt % of aspartic acid was used instead of arginine. Aspartic acid had a charge of −1 at a pH of 4.5.

Each of the CMP slurry compositions for polishing patterned tungsten wafers prepared in Examples was evaluated as to polishing characteristics under the following polishing evaluation conditions. Results are shown in Table 1.

Tungsten corrosion rate evaluation conditions:

Tungsten corrosion rate was measured at 50° C. For example, 5 wt % of hydrogen peroxide was added to the CMP slurry composition, which, in turn, was used to etch a blanket tungsten wafer (3 cm×3 cm), followed by calculation of a difference in film thickness before and after etching from electrical resistance measurements.

Polishing evaluation conditions:

1. Polishing machine: F-REX300X 300 mm (EBARA Corporation)

2. Polishing Conditions
Polishing pad: IC1010/SubaIV Stacked (Rodel Inc.)
Head speed: 101 rpm
Platen speed: 100 rpm
Down force: 2.5 psi
Retainer ring pressure: 8 psi
Slurry flow rate: 250 ml/min
Polishing time: 60 seconds

3. Polishing target
Evaluation of tungsten removal rate: A blanket wafer fabricated by sequentially depositing 300 Å of titanium nitride (TiN) and 6,000 Å of tungsten on a polycrystalline silicon substrate was used.
Evaluation of erosion: A patterned tungsten wafer (MIT 854, 300 mm) with exposed oxide/metal patterns was used. The patterned tungsten wafer was primarily polished on a polishing machine (Reflexion LK300 mm) with a polishing pad (IC1010/SubaIV Stacked, Rodel Inc.) using a CMP slurry for polishing tungsten (STARPLANAR6730, Samsung SDI) mixed with 2 wt % of hydrogen peroxide based on the weight of the slurry under conditions of: a head speed of 101 rpm, a platen speed of 100 rpm, a down force of 2 psi, a retainer ring pressure of 8 psi, a slurry flow rate of 240 ml/min, and a polishing time of 60 seconds. Through this primary polishing process, a tungsten film layer was removed, exposing the underlying oxide/metal patterns.

4. Analytical Methods
Tungsten Removal Rate (Unit: Å/min): A difference in film thickness before and after polishing under the aforementioned conditions was calculated form electrical resistance measurements.
Erosion (Unit: Å): After polishing under the aforementioned conditions, the profile of a 0.18 μm×0.18 μm L/S region on the wafer was measured using an atomic force microscope (Uvx-Gen3, Bruker Corporation), followed by calculation of erosion.

TABLE 1

| | | Example 1 | Example 2 | Example 3 | Example 4 | Example 5 | Example 6 |
|---|---|---|---|---|---|---|---|
| Component | Surface | 15 | 30 | 30 | 30 | 30 | 30 |
| | potential of | | | | | | |
| | particles | | | | | | |
| | (mV) | | | | | | |
| | Copper | 0.005 | 0.005 | 0.005 | 0.005 | 0.005 | 0.005 |
| | acetate | | | | | | |
| | (wt %) | | | | | | |
| | Copper | 17 | 17 | 17 | 17 | 17 | 17 |
| | cation (ppm) | | | | | | |
| | Iron catalyst | | | 0.005 | 0.005 | 0.005 | 0.005 |
| | (wt %) | | | | | | |
| | Iron cation | | | 6 | 6 | 6 | 6 |
| | (ppm) | | | | | | |
| | Complexing | Arginine | Arginine | Arginine | Lysine | Histidine | Polyamidoamine |
| | agent (wt %) | (0.05) | (0.05) | (0.05) | (0.05) | (0.05) | (0.01) |

| | | | | | | |
|---|---|---|---|---|---|---|
| Tungsten corrosion rate | 48 | 52 | 45 | 78 | 63 | 19 |
| (Å/min) | | | | | | |
| Tungsten removal rate | 352 | 422 | 463 | 355 | 346 | 340 |
| (Å/min) | | | | | | |
| Erosion (Å) | 273 | 229 | 207 | 224 | 238 | 202 |

TABLE 2

| | | Comparative | Comparative | Comparative | Comparative | Comparative |
|---|---|---|---|---|---|---|
| | | Example 1 | Example 2 | Example 3 | Example 4 | Example 5 |
| Component | Surface | 15 | 30 | 30 | 30 | 30 |
| | potential of | | | | | |
| | particles | | | | | |
| | (mV) | | | | | |
| | Copper | | | 0.005 | 0.005 | 0.005 |
| | acetate | | | | | |
| | (wt %) | | | | | |
| | Copper | | | 17 | 17 | 17 |
| | cation (ppm) | | | | | |
| | Iron catalyst | 0.005 | 0.005 | 0.005 | 0.005 | 0.005 |
| | (wt %) | | | | | |
| | Iron cation | 6 | 6 | 6 | 6 | 6 |
| | (ppm) | | | | | |
| | Complexing | Arginine | Arginine | Glycine | γ-aminobutyric acid | Aspartic acid |
| | agent (wt %) | (0.05) | (0.05) | (0.05) | (0.05) | (0.05) |

| | | | | | |
|---|---|---|---|---|---|
| Tungsten corrosion rate | 78 | 85 | 270 | 206 | 292 |
| (Å/min) | | | | | |
| Tungsten removal rate | 81 | 92 | 402 | 398 | 411 |
| (Å/min) | | | | | |
| Erosion (Å) | — | — | 382 | 379 | 398 |

Comparative Examples 1 and 2: Measurement of erosion was omitted due to a low tungsten removal rate.

As can be seen from the results shown in Table 1, the CMP slurry compositions of Examples could improve both a tungsten removal rate and flatness of a polished surface while reducing a tungsten corrosion rate.
Conversely, the CMP slurry compositions of Comparative Examples, free from the compound according to the present disclosure, were much less effective at reducing a tungsten corrosion rate and improving a tungsten removal rate and flatness of a polished surface, compared to the CMP slurry compositions of Examples.

It should be understood that various modifications, changes, alterations, and equivalent embodiments can be made by those skilled in the art without departing from the spirit and scope of the disclosure.

What is claimed is:

1. A CMP slurry composition for polishing patterned tungsten wafers, the CMP slurry composition comprising:
at least one of a polar solvent and a nonpolar solvent;
an abrasive agent; and
a catalyst,
wherein the catalyst comprises a copper-containing catalyst, the copper-containing catalyst being a complex of a copper cation and a complexing agent having a charge of +1 or more at a pH in a range of about 3 to about 6.

2. The CMP slurry composition as claimed in claim 1, wherein the copper cation comprises a copper (II) cation.

3. The CMP slurry composition as claimed in claim 1, wherein the complexing agent has a charge in a range of +1 to +10 at a pH in a range of about 3 to about 6.

4. The CMP slurry composition as claimed in claim 1, wherein the complexing agent comprises at least one of arginine, lysine, histidine, polyarginine, polylysine, and polyamidoamine.

5. The CMP slurry composition as claimed in claim 1, wherein:
the copper cation is present in an amount in a range of about 1 ppm to about 1,000 ppm in the CMP slurry composition; and
the complexing agent is present in an amount in a range of about 0.001 wt % to about 3 wt % in the CMP slurry composition.

6. The CMP slurry composition as claimed in claim 1, wherein the catalyst further comprises an iron-containing catalyst.

7. The CMP slurry composition as claimed in claim 6, wherein the iron-containing catalyst comprises at least one of an iron ion complex and a hydrate thereof.

8. The CMP slurry composition as claimed in claim 7, wherein the ferric cation-containing complex comprises at least one of ferric citrate, ammonium ferric citrate, Fe(III)-pTSA, Fe(III)-PDTA, Fe(III)-EDTA, and Fe(III)-DTPA.

9. The CMP slurry composition as claimed in claim 6, wherein an iron cation of the iron-containing catalyst is present in an amount in a range of about 1 ppm to about 1,000 ppm in the CMP slurry composition.

10. The CMP slurry composition as claimed in claim 1, wherein the abrasive agent comprises silica having a surface potential of +10 mV or more at a pH in a range of about 3 to about 6.

11. The CMP slurry composition as claimed in claim 1, wherein the abrasive agent is present in an amount in a range of about 0.001 wt % to about 20 wt % in the CMP slurry composition.

12. The CMP slurry composition as claimed in claim 1, further comprising at least one of an oxidizing agent and an amino acid.

13. The CMP slurry composition as claimed in claim 1, wherein the CMP slurry composition has a pH in a range of about 3 to about 6.

14. A method of polishing patterned tungsten wafers, the method comprising:
polishing a patterned tungsten wafer using the CMP slurry composition for polishing patterned tungsten wafers as claimed in claim 1.
